(19) United States
(12) Patent Application Publication
(10) Pub. No.: US 2006/0103563 A1
(43) Pub. Date: May 18, 2006

(54) Data driver, flat panel display and data converting method

(76) Inventor: Ji-Won Lee, Suwon (KR)

Correspondence Address: Robert E. Bushnell, Suite 300, 1522 K Street, N.W., Washington, DC, 20005, US

(21) Appl. No.: 11/232,430

(22) Filed: Sep. 22, 2005

(30) Foreign Application Priority Data
Oct. 28, 2004 (KR) 2004-86917

(51) Int. Cl. H03M 1/66

(52) U.S. Cl. 341/144

(57) ABSTRACT

A data driver in a flat panel display comprises: a latch for receiving a data signal in series, and for outputting the data signal in parallel; and a digital-to-analog (D/A) converter for converting the digital signal outputted by the latch into an analog signal. The D/A converter receives a reference signal having a voltage level which varies with time and outputs an output signal corresponding to a voltage level of the reference signal at a point in time when the reference signal has a voltage level the same as that of the digital signal. Thus, gradation of a data signal is represented on the basis of a reference signal, and therefore the gradation of the data signal is compensated by converting the reference signal, thereby compensating the gradation of the data signal without using an additional device. The latter functions correspond to the steps of a data converting method.

### CLAIM OF PRIORITY

This application makes reference to, incorporates the same herein, and claims all benefits accruing under 35 U.S.C. §119 from an application entitled DATA DRIVER, FLAT PANEL DISPLAY AND DATA CONVERTING METHOD, earlier filed in the Korean Intellectual Property Office on Oct. 28, 2004 and there duly assigned No. 2004-86917.

### BACKGROUND OF THE INVENTION

1. Technical Field

The present invention relates to a data driver, a flat panel display and a data converting method and, more particularly, to a data driver, a flat panel display and a data converting method in which gradation is represented according to the amplitude of a data signal.

2. Related Art

Various flat panel displays have recently been developed as alternatives to the relatively heavy and bulky cathode ray tube (CRT). Flat panel displays include the liquid crystal display (LCD), field emission display (FED), plasma display panel (PDP), organic light emitting 8 display employing an organic light emitting device (OLED), and the like.

In the flat panel display, a display region is defined by arranging a plurality of pixels in a matrix form on a substrate, and each pixel is connected with a scan line and a data line. A data signal is selectively applied to the pixel, thereby displaying an image. Furthermore, the flat panel display comprises a data driver for outputting the data signal and a scan driver for outputting a scan signal.

The data driver receives a digital data signal and converts the digital data signal into an analog data signal so that gradation is represented on the basis of the amplitude of the data signal.

A digital-to-analog (D/A) converter comprises a distributor which has an input terminal for receiving a first voltage Vdd and a plurality of registers for distributing the first voltage Vdd, an output terminal for outputting the distributed voltages, and an input part for receiving a digital signal of four bits.

The distributor comprises fifteen registers which are placed between the input terminal and a Vss terminal, and which are connected in series, thereby distributing a contrast control signal into sixteen voltages through the respective registers.

The output terminal comprises four transistors which are connected in series, and which connect a source electrode to a drain electrode. Furthermore, the output terminal is connected to a junction between the input terminal of the distributor and a first register, to a junction between the fifteenth register and the Vss terminal, and to respective junctions between the respective first through fifteenth registers, so that sixteen output terminals are connected to the distributor.

Furthermore, the respective transistors connected to each output terminal of the distributor are turned on/off in response to signals applied to their gate electrodes, and a signal is outputted through the output terminals of the distributor under the condition that four transistors are all turned on.

The input part receives the digital data signal of four bits, and selectively turns on/off four transistors connected to the output terminal. In this regard, each digital data signal of four bits is inputted to the input part through two lines, so that the digital data signals are inputted through a total of eight lines.

Meanwhile, one line of two lines connected to the same input terminal is connected to an inverter, and the other line is not connected to the inverter. Furthermore, four switches provided in respective switching terminals select four lines among eight lines, and are connected to the gate electrode of the transistor, so that each switch is turned on/off by the digital data signal. Therefore, the distributed contrast signal is outputted through only one switching terminal among sixteen switching terminals in correspondence to the digital data signal of four bits. Thus, sixteen analog data signals are outputted by four digital signals.

Furthermore, a level of the voltage distributed to each register placed between the control terminal and the Vss terminal is adjusted by adjusting the level of the first voltage Vdd supplied through the input terminal, thereby adjusting the voltage level of the analog data signal.

However, the flat panel display employing the D/A converter is in need of an additional device to convert the data signal in order to compensate the data signal. Thus, a process for compensating the data signal is difficult. Furthermore, the additional device increases the production cost of the flat panel display.

### SUMMARY OF THE INVENTION

Accordingly, it is an aspect of the present invention to provide a data driver, a flat panel display and a data converting method, in which gradation of a data signal is represented on the basis of a reference signal, and thus the gradation of the data signal is compensated by converting the reference signal, thereby compensating the gradation of the data signal without using an additional device.

The forgoing and/or other aspects of the present invention are achieved by providing a data driver comprising: a latch for receiving a data signal in series and for outputting the data signal in parallel; and a digital-to-analog (D/A) converter for converting a digital signal outputted from the latch to an analog signal. The D/A converter receives a reference signal having a voltage level which varies with time, and outputs an output signal corresponding to the voltage level of the reference signal at a point in time when the reference signal has the same voltage level as the digital signal.

Other aspects of the present invention are achieved by providing a flat panel display comprising: a pixel portion which includes a plurality of pixels defined by a data line and a scan line; a data driver comprising a latch for receiving a data signal in series, and for outputting the data signal in parallel, and a D/A converter for converting a digital signal outputted from the latch into an analog signal; and a scan driver for transmitting a scan signal to the pixel portion. The D/A converter receives a reference signal having a voltage level which varies with time, and outputs an output signal corresponding to the voltage level of the reference signal at a point in time when the reference signal has the same voltage level as the digital signal.

Still other aspects of the present invention are achieved by providing a method of converting a digital signal into an analog signal, the method comprising the steps of: receiving the digital signal and a reference signal having a voltage level which varies with time; and outputting an output signal corresponding to the voltage level of the reference signal at a point in time when the reference signal has the same voltage level as the digital signal.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a circuit diagram of a digital-to-analog (D/A) converter;

FIG. 2 illustrates the configuration of a flat panel display according to an embodiment of the present invention;

FIG. 3 is a block diagram of a data driver employed in the flat panel display according to an embodiment of the present invention;

FIG. 4 is a block diagram of a D/A converter employed in the data driver according to an embodiment of the present invention;

FIG. 5 are waveforms illustrating the operation of the D/A converter according to an embodiment of the present invention;

FIG. 6 is a waveform of a reference signal; and

FIG. 7 schematically illustrates the structure of a pixel employed in the flat panel display according to an embodiment of the present invention.

### DETAILED DESCRIPTION OF INVENTION

Hereinafter, preferred embodiments according to the present invention will be described in detail with reference to the accompanying drawings, the preferred embodiments being provided so as to be readily understood by those skilled in the art, so that various modifications will be apparent, and so that the present invention is not limited to the embodiments disclosed herein.

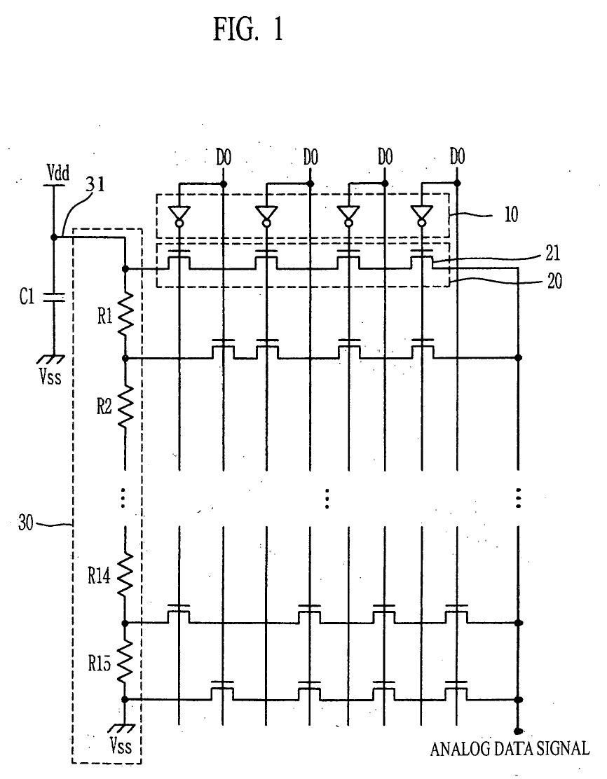

FIG. 1 is a circuit diagram of a digital-to-analog (D/A) converter.

Referring to FIG. 1, the D/A converter comprises a distributor 30 having an input terminal 31 for receiving a first voltage Vdd and a plurality of registers R1, R2, . . . , R14, R15 for distributing the first voltage Vdd, an output terminal 20 for outputting the distributed voltages, and an input part 10 for receiving a digital signal of four bits.

The distributor 30 comprises fifteen registers R1, R2, . . . , R14, RI5 which are placed between the input terminal 31 and a Vss terminal, and which are connected in series, thereby distributing a contrast control signal into sixteen voltages through the respective registers R1, R2, . . . , R14, R15.

The output terminal 20 comprises four transistors 21, which are connected in series, and which connect a source electrode to a drain electrode. Furthermore, an output terminal 20 is connected to a junction between the input terminal 31 and a first register R1, to a junction between the fifteenth register R15 and the Vss terminal, and to respective junctions between the respective first through fifteenth registers R1 through R15, so that sixteen output terminals are connected to the distributor 30.

Furthermore, the respective transistors 21 connected to each output terminal of the distributor 30 are turned on/off in response to signals applied to their gate electrodes, and a signal is outputted through the output terminals of the distributor 30 under the condition that four transistors 21 are all turned on.

The input part 10 receives the digital data signal of four bits, and selectively turns on/off four transistors 21 connected to the output terminal. In this regard, each digital data signal of four bits is inputted to the input part 10 through two lines, so that the digital data signals are inputted through a total of eight lines.

Meanwhile, one line of two lines connected to the same input terminal is connected to an inverter, and the other line is not connected to the inverter. Furthermore, four switches provided in respective switching terminals select four lines among eight lines, and are connected to the gate electrode of the transistor 21, so that each switch is turned on/off by the digital data signal. Therefore, the distributed contrast signal is outputted through only one switching terminal among sixteen switching terminals in correspondence to the digital data signal of four bits. Thus, sixteen analog data signals are outputted by four digital signals.

Furthermore, the level of the voltage distributed to each register placed between the control terminal and the Vss terminal is adjusted by adjusting the level of the first voltage Vdd supplied through the input terminal, thereby adjusting the voltage level of the analog data signal.

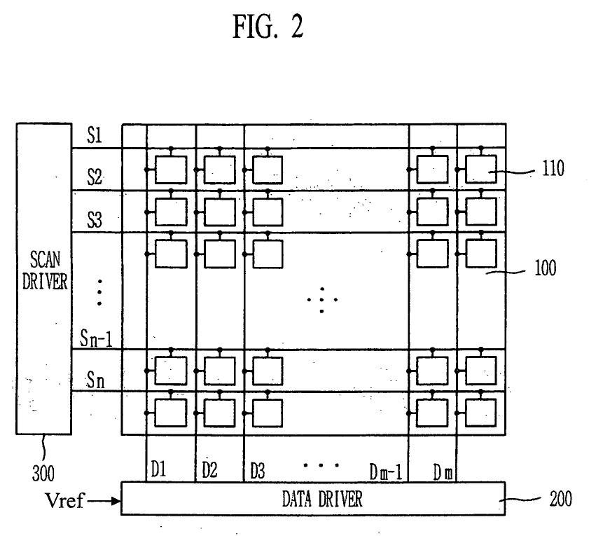

FIG. 2 illustrates the configuration of a flat panel display according to an embodiment of the present invention.

Referring to FIG. 2, a flat panel display comprises a pixel portion 100 for displaying 8 an image, a data driver 200 for transmitting a data signal to the pixel portion 100, and a scan driver for transmitting a scan signal to the pixel portion 100.

The pixel portion 100 comprises: a plurality of data lines D1, D2, . . . , Dm-1, Dm; a plurality of scan lines S1, S2, . . . , Sn-1, Sn; and a plurality of pixels 110 intersected by the plurality of data lines D1, D2, . . . , Dm-1, Dm and the plurality of scan lines S1, S2, . . . , Sn-1, Sn. Each pixel 110 comprises a gate electrode and a cathode electrode, and receives the data signal and the scan signal from one of the data lines D1, D2, . . . , Dm-1, Dm and one of the scan lines S1, S2, . . . , Sn-1, Sn, respectively.

The plurality of pixels 110 arranged on one horizontal line are selected in sequence by the scan signals transmitted through the plurality of scan lines S1, S2, . . . , Sn-1, Sn, and the selected pixel receives the data signal transmitted through the data lines D1, D2, . . . , Dm-1, Dm, thereby emitting light.

The data driver 200 applies the data signals to the data lines D1, D2, . . . , Dm-1, Dm, wherein the data signal represents gradation according to the amplitude thereof. The data driver 200 receives an external reference signal Vref, and compares the reference signal Vref with the data signal, thereby determining the amplitude of the data signal.

The scan driver 300 applies a low signal to the scan lines S1, S2, . . . , Sn-1, Sn for a predetermined period with regard to each horizontal line of the pixel portion 100, thereby selecting the pixels arranged on a predetermined horizontal line for this period.

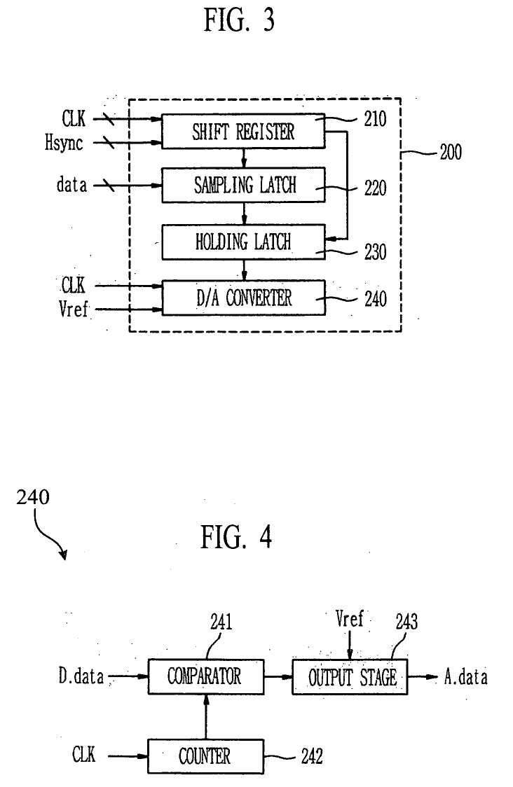

FIG. 3 is a block diagram of a data driver employed in the flat panel display according to an embodiment of the present invention.

Referring to FIG. 3, the data driver 200 comprises a shift register 210, a sampling latch 220, a holding latch 230, and a digital/analog (D/A) converter 240.

The shift register 210 comprises a plurality of flipflops, and controls the sampling latch 220 on the basis of a clock signal CLK and a horizontal synchronous signal Hsync. The sampling latch 220 receives the data signals corresponding to one horizontal line in series according to a control signal outputted from the shift register 210, and outputs the data signals in parallel. In this regard, the method of receiving the signals in series and outputting the signals in parallel is called “serial in parallel out” (SIPO). The holding latch 230 receives the data signal in parallel, and outputs the data signal in parallel. In this regard, the method of receiving the signals in parallel and outputting the signals in parallel is called “parallel in parallel out” (PIPO). The D/A converter 240 converts a digital data signal into an analog data signal.

FIG. 4 is a block diagram of a D/A converter employed in the data driver according to an embodiment of the present invention.

Referring to FIG. 4, the D/A converter 240 comprises a comparator 241, a counter 242, and an output stage 243.

The comparator 241 receives the digital data signal D.data from the holding latch 230 and a discrete signal from the counter 242, and compares the digital data signal D.data with the discrete signal. When the digital data signal D.data is equal to the discrete signal, the comparator 241 outputs a control signal.

The counter 242 is a clock counter. Thus, the counter 242 receives a clock CLK and outputs bit values in sequence corresponding to a bit value between a minimum bit value and a maximum bit value of the digital data signal D.data.

The output stage 243 outputs an output signal on the basis of the control signal of the comparator 241 and the reference signal Vref. When the comparator 241 outputs the control signal while the reference signal Vref is transmitted to the output stage 243, the output stage 243 outputs a signal having a voltage level corresponding to the reference signal Vref when the control signal is outputted by the comparator 241. At this point, the output stage 243 outputs the analog data signal A.data.

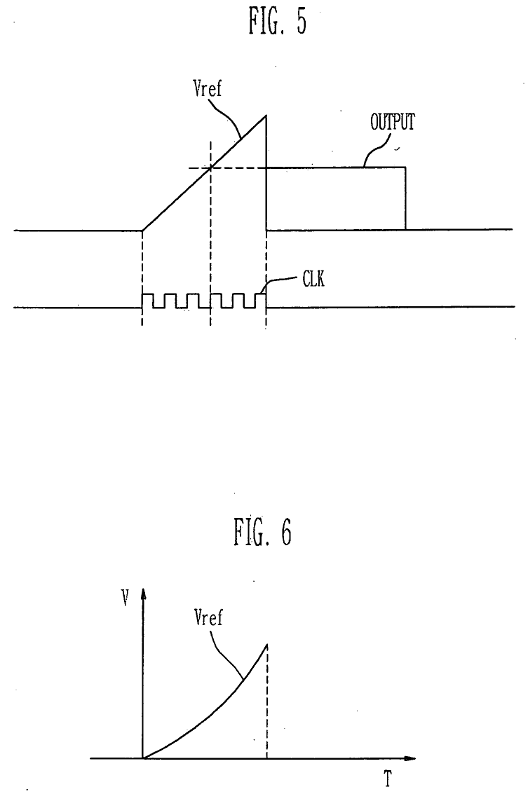

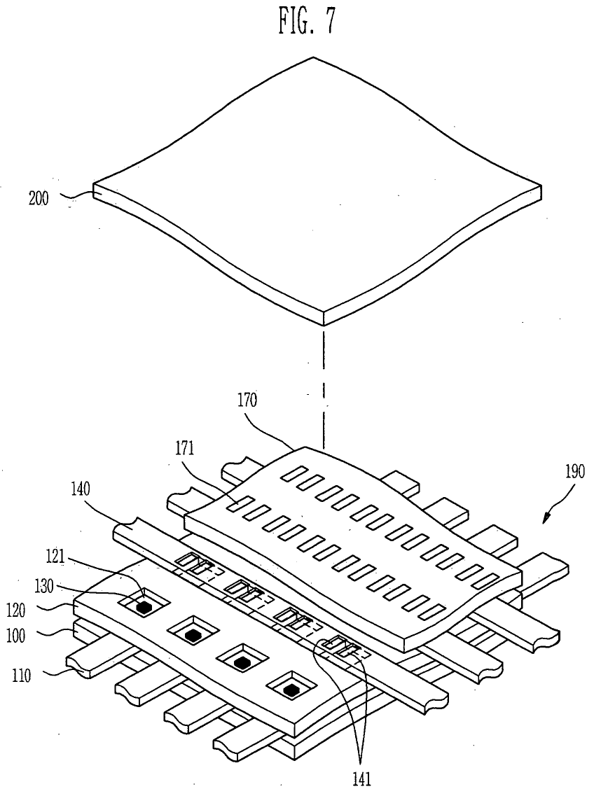

FIG. 5 are waveforms illustrating the operation of the D/A converter according to an embodiment of the present invention, and FIG. 6 is a waveform of a reference signal.

Referring to FIGS. 5 and 6, the D/A converter 240 operates by receiving the clock CLK, the digital data signal D.data, and the reference signal Vref having a ramp waveform.

When the comparator 241 of the D/A converter 240 receives the clock CLK and the digital data signal D.data, the counter 242 starts counting the clock CLK, and outputs discrete signals to the comparator 241 in sequence. The comparator 241 continuously compares the discrete signals from the counter 242 with the digital data signal D.data, and determines whether the discrete signal is equal to the digital data signal D.data. In other words, when the digital data signal is of 7 bits, the counter 242 outputs a discrete signal of 7 bits, i.e., outputs the discrete signals corresponding to a minimum bit value of 0 through a maximum bit value of 127. Furthermore, when the digital data signal D.data has a bit value of 45, the comparator 241 continuously compares the digital data signal D.data with the discrete signal of the counter 242, and determines whether the discrete signal is equal to the bit value of 45, thereby outputting the control signal to the output stage 243 at a point in time when the discrete signal is equal to the bit value of 45. Likewise, when the digital data signal D.data has a bit value of 90, the comparator 241 outputs the control signal to the output stage 243 at a point in time when the counter 242 outputs a discrete signal equal to the bit value of 90. Thus, the control signal is outputted from the comparator 241 at different times according to the digital data signal D.data.

Furthermore, the reference signal Vref having the ramp waveform and the control signal outputted from the comparator 241 are inputted to the output stage 243. Here, the reference signal Vref is repeated per predetermined period, and the control signal is transmitted once to the output stage within one period. For one period, a point in time when the control signal is transmitted to the output stage 243, in the case of a digital signal D.data having the bit value of 45, is different from the point in time when the control signal is transmitted to the output stage 243, in the case of a digital signal D.data having the bit value of 90. Therefore, the reference signal Vref which has a voltage level which varies with time is different between the digital data signals D.data having the bit values 45 and 90, so that the output stage 243 outputs the analog data signal A.data having different voltage levels. Thus, the analog data signal A.data outputted by the output stage 243 has a voltage level which is different according to the digital data signal D.data, thereby representing the gradation.

Furthermore, even though the same digital data signal D.data is inputted, the gradation can be variously represented by varying the voltage level of the reference signal Vref. For example, two reference signals which are different in gradient are different in a voltage level at the same point in time, so that the analog data signals A.data corresponding to the respective voltage levels of the reference signals are also different from each other. Thus, the gradation can be easily compensated by using the variation of the reference signal.

Meanwhile, the reference signal Vref may have a nonlinear waveform as shown in FIG. 6.

Furthermore, in FIG. 5, discrete signals are outputted from the counter 242 at regular intervals. Alternatively, the discrete signals may be outputted from the counter 242 at irregular intervals. In the case where the reference signal Vref is linear and the discrete signals are outputted from the counter 242 at irregular intervals, the gradation is nonlinearly represented by the linear reference signal.

FIG. 7 schematically illustrates the structure of a pixel employed in the flat panel display according to an embodiment of the present invention.

Referring to FIG. 7, a flat panel display comprises a lower substrate 190, an upper substrate 200, a spacer (not shown), and a mesh electrode 170. The lower substrate 190 comprises a rear substrate 100, a cathode electrode 110, an insulating layer 120, electron emission parts 130, and a gate electrode 140. Furthermore, the upper substrate 200 comprises a front substrate (not shown), an anode electrode (not shown), and a fluorescent layer (not shown).

In the lower substrate 190, at least one cathode electrode 110 is formed on the rear substrate 100 in a stripe form. Furthermore, the insulating layer 120 has a plurality of first holes 121 and is formed on the cathode electrode 110, exposing a predetermined portion of the cathode electrode 110. In addition, the gate electrode 140 is formed on the insulating layer 120. The gate electrode 140 is formed with a plurality of second holes 141 having a uniform size, wherein each second hole 141 is overlapped with a first hole 121. Meanwhile, the electron emission part 130 is placed on the cathode electrode 110 at a region where the first hole 121 and the second hole 141 overlap each other.

The rear substrate 100 comprises a glass or silicon substrate. In the case where the electron emission part 130 is formed by applying rear-exposure to a paste, the rear substrate 100 preferably includes a transparent substrate, such as a glass substrate.

The cathode electrode 110 supplies a data signal and a scan signal from a data driver (not shown) and a scan driver (not shown), respectively, to each respective electron emission part 130. In this regard, each electron emission part 130 is formed in a region defined by the intersection of a cathode electrode 110 and a gate electrode 140. Preferably, the cathode electrode 120 is made of indium tin oxide (ITO).

The insulating layer 120 is formed on the rear substrate 100 and each cathode electrode 110, and electrically insulates each cathode electrode 110 from gate electrode 140.

The gate electrode 140 is formed on the insulating layer 120 in a predetermined form, such as a stripe shape, and is arranged to intersect the cathode electrode 110. In this regard, the gate electrode 140 supplies the data signal and the scan signal from the data driver 200 and the scan driver 300 (FIG. 2), respectively, to a pixel. The gate electrode 140 is made of metal having good conductivity and, for example, includes at least one conductive metal material selected from the group consisting of gold (Au), silver (Ag), platinum (Pt), aluminum (Al), chrome (Cr), and alloy thereof.

The electron emission part 130 is placed on the cathode electrode 110, is exposed through the first hole 121 of the insulating layer 120, and is electrically connected to the cathode electrode 110. In order to make the electron emission part 130 emit electrons when an electric field is formed between the cathode electrode 110 and an anode electrode, the electron emission part 130 is preferably made of carbon material, nano material, graphite, graphite nano fiber, diamond-like-carbon, fullerene (C60), silicon nano wire, or a combination thereof.

When an electric field is formed by voltage applied between the cathode electrode 110 and the gate electrode 140, the electron emission part 130 emits the electrons, and the electrons collide with the fluorescent layer formed on the upper substrate 200, thereby forming a predetermined image.

The mesh electrode 170 is formed on the gate electrode 140, controls a trajectory of the electron emitted from the electron emission part 130, and protects the electron emission part 130 from an anode electric field caused by high voltage. As shown in FIG. 7, the mesh electrode 170 is formed with mesh holes 171 through which the electron emission part 130 is exposed. The mesh holes 171 are gradually narrowed as they extend from the lower substrate 190 toward the upper substrate 200.

Additionally, an insulating layer (not shown) can be interposed between the mesh electrode 170 and the gate electrode 140, thereby insulating the mesh electrode 170 from the gate electrode 140. Furthermore, the insulating layer is formed in one side of the mesh electrode 170, and enhances the withstanding of voltage in an electron emission region. The insulating layer preferably comprises lead oxide (PbO) or silicon dioxide (SiO₂).

As described above, the present invention provides a data driver, a flat panel display, and a data converting method, in which gradation of a data signal is represented on the basis of a reference signal, and thus the gradation of the data signal is compensated by converting the reference signal, thereby compensating the gradation of the data signal without using an additional device, and reducing production cost of the flat panel display.

Although a preferred embodiment of the present invention has been shown and described, it will be appreciated by those skilled in the art that changes may be made in this embodiment without departing from the principles and spirit of the invention, the scope of which is defined by the claims and their equivalents.

What is claimed is:

1. A data driver, comprising:
a latch for receiving a data signal in series, and for outputting the data signal in parallel; and
a digital-to-analog (D/A) converter for converting a digital signal outputted by the latch into an analog signal;
wherein the D/A converter receives a reference signal having a voltage level which varies with time, and outputs an output signal corresponding to the voltage level of the reference signal at a point in time when the voltage level of the reference signal is equal to a voltage level of the digital signal.

2. The data driver according to claim 1, wherein the D/A converter comprises:
a counter for receiving a clock signal, and for outputting a discrete signal between a minimum bit value and a maximum bit value of the digital signal in correspondence to the clock signal;
a comparator for comparing the digital signal with the discrete signal, and for outputting a control signal when a value of the digital signal is equal to a value of the discrete signal; and
an output stage for receiving the control signal and the reference signal, and for outputting an output signal having a voltage level equal to the voltage level of the reference signal at a point in time when the control signal is inputted.

3. The data driver according to claim 2, wherein the discrete signal is outputted from the counter at one of regular intervals and irregular intervals.

4. The data driver according to claim 1, wherein the reference signal is maintained in one of an increasing state and a decreasing state as time passes.

5. The data driver according to claim 1, wherein the reference signal comprises one of a linear signal and a nonlinear signal.

6. The data driver according to claim 1, wherein the reference signal is adjustable with respect to a voltage level thereof.

7. A flat panel display, comprising:
a pixel portion comprising a plurality of pixels, each pixel being defined by a data line and a scan line;
a data driver comprising a latch for receiving a data signal in series and for outputting the data signal in parallel, and a digital-to-analog (D/A) converter for converting a digital signal outputted by the latch into an analog signal; and
a scan driver for transmitting a scan signal to the pixel portion;
wherein the D/A converter receives a reference signal having a voltage level which varies with time, and outputs an output signal corresponding to the voltage level of the reference signal at a point in time when the voltage level of the reference signal is equal to a voltage level of the digital signal.

8. The flat panel display according to claim 7, wherein the D/A converter comprises:
a counter for receiving a clock signal, and for outputting a discrete signal between a minimum bit value and a maximum bit value of the digital signal in correspondence to the clock signal;
a comparator for comparing the digital signal with the discrete signal, and for outputting a control signal when a value of the digital signal is equal to a value of the discrete signal; and
an output stage for receiving the control signal and the reference signal, and for outputting an output signal having a voltage level equal to the voltage level of the reference signal at a point in time when the control signal is inputted.

9. The flat panel display according to claim 8, wherein the discrete signal is outputted from the counter at one of regular intervals and irregular intervals.

10. The flat panel display according to claim 7, wherein the reference signal is maintained in one of an increasing state and a decreasing state as time passes.

11. The flat panel display according to claim 7, wherein the reference signal comprises one of a linear signal and a nonlinear signal.

12. The flat panel display according to claim 7, wherein the reference signal is adjustable with respect to a voltage level thereof.

13. The flat panel display according to claim 7, wherein the pixel portion comprises:
a rear substrate;
a cathode electrode formed on the rear substrate in a stripe form;
a first insulating layer formed on the rear substrate and the cathode electrode, and having a first hole for exposing a portion of the cathode electrode;
a gate electrode formed on the first insulating layer, said gate electrode intersecting the cathode electrode and having a second hole corresponding to the first hole of the first insulating layer; and
an electron emission part formed on the cathode electrode in correspondence to the second hole.

14. The flat panel display according to claim 13, further comprising a mesh electrode formed on the gate electrode.

15. A method of converting a digital signal into an analog signal, the method comprising the steps of:
receiving the digital signal and a reference signal having a voltage level which varies with time; and
outputting an output signal corresponding to the voltage level of the reference signal at a point in time when the voltage level of the reference signal is equal to a voltage level of the digital signal.

16. The method according to claim 15, wherein the reference signal is maintained in one of an increasing state and a decreasing state as time passes.

17. The method according to claim 15, wherein the reference signal comprises one of a linear signal and a nonlinear signal.

18. The method according to claim 15, wherein the reference signal is adjustable with respect to a voltage level thereof.

19. The method according to claim 15, wherein the point in time when the a voltage level of the reference signal is equal to the voltage level of the digital signal is determined when a signal, outputted in sequence and indicating a bit value between a minimum bit value and a maximum bit value of the digital signal, matches a bit value of the digital signal.

20. The method according to claim 19, further comprising the step of providing a counter, and wherein the signal indicating the bit value between the minimum bit value and the maximum bit value of the digital signal is outputted by the counter in sequence.

21. The method according to claim 19, wherein the signal indicating the bit value between the minimum bit value and the maximum bit value of the digital signal is outputted at one of regular intervals and irregular intervals.
